(19) United States
(12) Patent Application Publication
(10) Pub. No.: US 2026/0342321 A1
(43) Pub. Date: Oct. 29, 2026

(54) Power noise reduction adapter

(71) Applicant: Chung-Liang Lin, New Taipei City (TW)

(72) Inventor: Chung-Liang Lin, New Taipei City (TW)

(21) Appl. No.: 19/436,270

(22) Filed: Dec. 30, 2025

(30) Foreign Application Priority Data
Jan. 3, 2025 (TW) 114200110

(51) Int. Cl. H03K 5/1252; H03K 5/00

(52) U.S. Cl. CPC H03K 5/1252; H03K 5/00006

(57) ABSTRACT

A power noise reduction adapter receives an input power signal and shunts the input power signal into a first shunt power signal, a second shunt power signal and a third shunt through a parallel connection. The power noise reduction adapter performs voltage reduction and current limiting on the first shunt power signal, performs at least one frequency division on the first shunt power signal after the voltage reduction and current limiting, and is used to output at least one frequency division signal. The power noise reduction adapter acquires and accumulates noise signals from the second shunt power signal to generate a noise accumulation signal, and outputs a trigger signal when the noise accumulation signal accumulates to a threshold value. The power noise reduction adapter uses the third shunt power signal as an output power signal of the power noise reduction adapter.

### TECHNICAL FIELD

The present invention relates to a power noise reduction adapter and an electrical device, and more particularly to a power noise reduction adapter configured to generate a purified alternating current power signal for use by various types of electrical devices.

### BACKGROUND

Food processing devices often require the use of an alternating current power signal as a power source during food processing. For example, espresso machines or steam tea brewing machines use high-pressure and high-temperature steam to extract components from coffee beans or tea leaves in order to obtain coffee or tea. When the alternating current power signal contains a relatively large amount of noise, the stability of steam pressure and/or temperature may be affected, thereby causing the flavor and quality of the extracted coffee or tea to be inferior to expectations.

For another example, coffee grinders and spice grinders are driven by an alternating current power signal to operate grinding blades. When the alternating current power signal contains excessive noise, the particle size distribution and flavor of the ground coffee or spices may be inconsistent or unsatisfactory. For yet another example, bread makers, brewing machines, or dairy fermentation machines primarily rely on an alternating current power signal to control fermentation temperature. If the fermentation temperature becomes unstable due to noise in the alternating current power signal, the taste of the produced food may be adversely affected.

However, food processing devices are generally regarded as electrical products that do not require high signal precision. As a result, noise contained in the alternating current power signal is typically not processed or mitigated. In other words, noise in the alternating current power signal may negatively affect the taste of food processed by food processing devices. Therefore, in order to improve the quality and flavor of food produced by food processing devices, there is a need for a solution capable of processing or reducing noise in an alternating current power signal. In addition to food processing devices, other types of electrical devices may also suffer from reduced efficiency and performance due to noise present in an alternating current power signal.

The present invention has arisen to mitigate and/or obviate the afore-described disadvantages.

### SUMMARY

A primary aspect of the present invention is to provide a power noise reduction adapter by which a noise in an alternating current input power signal is reduced, so as to generate a purified output power signal for use by various types of electrical devices.

To obtain above-mentioned aspect, a power noise reduction adapter provided by the present invention contains: an input wire, a first shunt wire, a second shunt wire, a third shunt wire, a voltage reduction and current limiting device, a frequency division noise reduction device, a noise acquisition accumulation triggering device, an output wire, and a noise releasing device.

The input wire is configured to receive an alternating current input power signal. The first shunt wire, the second shunt wire, and the third shunt wire are electrically connected to the input wire, wherein the input power signal generates a first shunt power signal, a second shunt power signal, and a third shunt power signal on the first shunt wire, the second shunt wire, and the third shunt wire, respectively.

The voltage reduction and current limiting device is electrically connected to the first shunt wire and is configured to perform voltage reduction and current limiting on the first shunt power signal. The frequency division noise reduction device is electrically connected to the voltage reduction and current limiting device and is configured to perform at least one frequency division on the first shunt power signal after the voltage reduction and current limiting, and to output at least one frequency division signal.

The noise acquisition accumulation triggering device is electrically connected to the second shunt wire and is configured to acquire and accumulate a plurality of noise signals from the second shunt power signal to generate a noise accumulation signal, and to output a trigger signal when the noise accumulation signal accumulates to a threshold value.

The output wire is electrically connected to the third shunt wire and is configured to use the third shunt power signal as an output power signal of the power noise reduction adapter. The noise releasing device is electrically connected to the frequency division noise reduction device and the noise acquisition accumulation triggering device, and is configured to receive and release the frequency division signal and the trigger signal.

Preferably, in one embodiment of the power noise reduction adapter, the noise releasing device is a light-emitting device. The light-emitting device includes a plurality of light-emitting units and is configured to receive the trigger signal and the frequency division signal, wherein the plurality of light-emitting units emit light according to the trigger signal and the frequency division signal.

Preferably, in one embodiment of the power noise reduction adapter, the frequency division noise reduction device includes a plurality of frequency division units connected in series. The plurality of frequency division units are configured to perform one to multiple frequency divisions on the first shunt power signal and to output a plurality of frequency division signals corresponding to the one to multiple frequency divisions.

Preferably, in one embodiment of the power noise reduction adapter, a division ratio of each of the plurality of frequency division units is an even number, such as 2.

Preferably, in one embodiment of the power noise reduction adapter, the input power signal is an alternating current mains power signal having a frequency of 50 Hz or 60 Hz and a voltage ranging from 100 volts to 240 volts.

Preferably, in one embodiment of the power noise reduction adapter, the noise acquisition accumulation triggering device includes a high-voltage capacitor pulse transformer and a control chip electrically connected to each other to acquire and accumulate the plurality of noise signals, and the voltage reduction and current limiting device includes a high-voltage capacitor and a current limiting device electrically connected to each other to perform voltage reduction and current limiting.

Preferably, in one embodiment of the power noise reduction adapter, the power noise reduction adapter is independently disposed outside an electrical device and is electrically connected to a power module of the electrical device, and the power module receives the output power signal for use by the electrical device.

Preferably, in one embodiment of the power noise reduction adapter, the power noise reduction adapter further includes a housing, wherein the input wire, the first shunt wire, the second shunt wire, the third shunt wire, the voltage reduction and current limiting device, the frequency division noise reduction device, the noise acquisition accumulation triggering device, and the light-emitting device are disposed within the housing. The housing is provided with at least one opening, an input power socket, and an output power socket, the opening being configured to expose a light-emitting portion of the light-emitting device, the input power socket and the output power socket being configured to connect the input wire and the output wire, respectively, and the input power socket and the output power socket being configured to connect an input power cable and an output power cable, respectively.

Another aspect of the present invention is to provide an electrical device which includes a power module and the aforementioned power noise reduction adapter. The power noise reduction adapter is electrically connected to the power module, wherein the power module receives the output power signal for use by the electrical device.

Preferably, in one embodiment of the electrical device, the electrical device is an espresso machine, a coffee grinder, a spice grinder, a bread maker, a brewing machine, a dairy fermentation machine, or a steam tea brewing machine.

As described above, compared with the prior art, the power noise reduction adapter provided by the present invention is capable of effectively releasing noise of the input power signal to ground through a specific processing path, such that an output power signal corresponding to the input power signal has reduced noise or is substantially free of noise. Accordingly, it is possible to prevent the output power signal, when used by the electrical device, from causing degraded efficiency and performance due to noise.

### BRIEF DESCRIPTION OF THE DRAWINGS

FIG. 1 is a block diagram of a food processing device for enhancing food palatability according to a preferred embodiment of the present invention.

FIG. 2 is a block diagram of a food processing device for enhancing food palatability according to another preferred embodiment of the present invention.

FIG. 3 is a block diagram of a power noise reduction adapter for enhancing food palatability of a food processing device according to the preferred embodiment of the present invention.

FIG. 4 is a flowchart of a power noise reduction method for enhancing food palatability of a food processing device according to the preferred embodiment of the present invention.

### DETAILED DESCRIPTION

A power noise reduction adapter and an electrical device according to a preferred embodiment of the present invention mainly shunt an input power signal into three shunt power signals through a parallel connection. One of the three shunt power signals is subjected to voltage reduction, current limiting, and frequency division; another one of the three shunt power signals is subjected to acquisition and accumulation of noise, and the other one of the three shunt power signals is used as an output power signal. Through the processing performed on the two shunt power signals, a specific grounding effect is equivalently generated, such that noise contained in the input power signal is guided out. Accordingly, noise contained in the output power signal is suppressed and reduced, such that the output power signal becomes a purified alternating current power signal. The following description is provided with reference to the accompanying drawings to illustrate possible embodiments of the present invention in detail. It is to be noted that the following embodiment details are not intended to limit the scope of the present invention as claimed, but are merely provided to facilitate understanding by those having ordinary skill in the art. Although the following embodiments are described by taking a food processing device as an example to implement the electrical device, the present invention is not limited to the type of the electrical device.

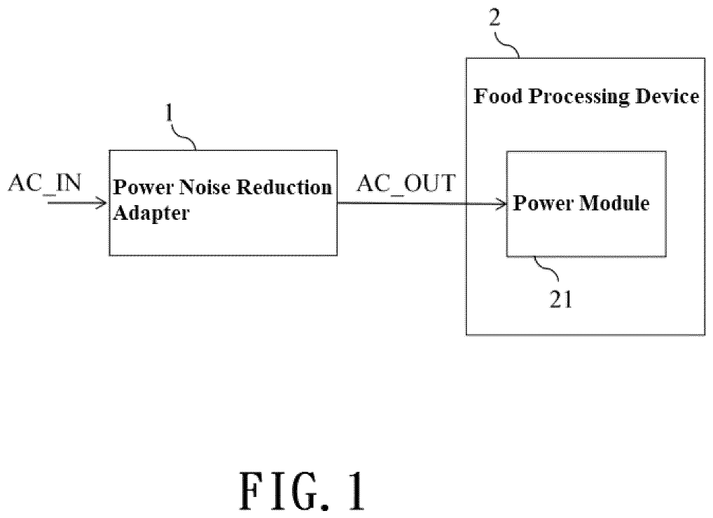

FIG. 1 is a block diagram of a food processing device for enhancing food palatability according to a preferred embodiment of the present invention. The food processing device 2 includes a power module 21. The power module 21 is configured to receive an output power signal AC_OUT output from a power noise reduction adapter 1. The output power signal AC_OUT is an alternating current power signal. After the power noise reduction adapter 1 processes an input power signal AC_IN, the output power signal AC_OUT is a power signal having reduced noise or substantially free of noise. In this embodiment, the power noise reduction adapter 1 is independently disposed outside the food processing device 2 and is electrically connected to the power module 21 of the food processing device 2. The power module 21 receives the output power signal AC_OUT, such that the food processing device 2 uses the output power signal AC_OUT to process food.

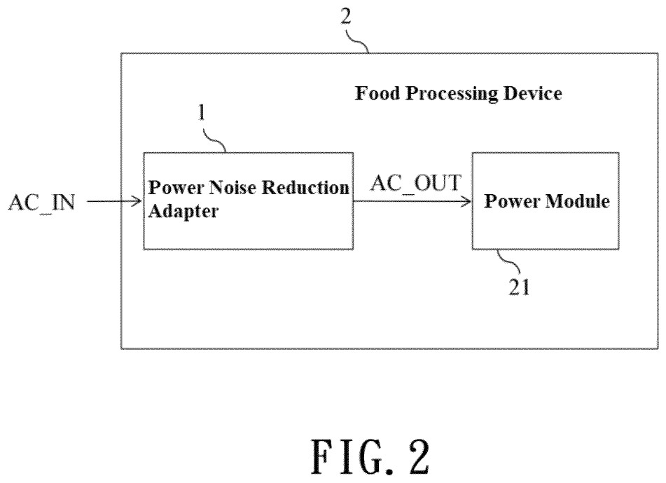

FIG. 2 is a block diagram of a food processing device for enhancing food palatability according to another preferred embodiment of the present invention. Different from the embodiment shown in FIG. 1, in this embodiment, the power noise reduction adapter 1 is disposed inside the food processing device 2. Furthermore, in both the embodiments shown in FIG. 1 and FIG. 2, the food processing device 2 is an espresso machine, a coffee grinder, a spice grinder, a bread maker, a brewing machine, a dairy fermentation machine, or a steam tea brewing machine. However, the present invention is not limited thereto.

Taking an espresso machine as an example, the espresso machine is configured to produce espresso. A crema formed on a top layer of the espresso is consumed before dissipation; otherwise, a smooth mouthfeel is lost. A golden-colored crema is a key factor that provides layered flavor and desirable taste to the espresso. In order to extract the golden-colored crema from coffee beans, steam must be stably maintained at a pressure of 9 bar and at a specific temperature. The power noise reduction adapter 1 of the present invention is capable of providing the output power signal AC_OUT having reduced noise or substantially free of noise. Accordingly, an espresso machine using the power noise reduction adapter 1 of the present invention is able to stably maintain steam at 9 bar and at the specific temperature, such that each cup of espresso produced has the golden-colored crema, thus enhancing food palatability.

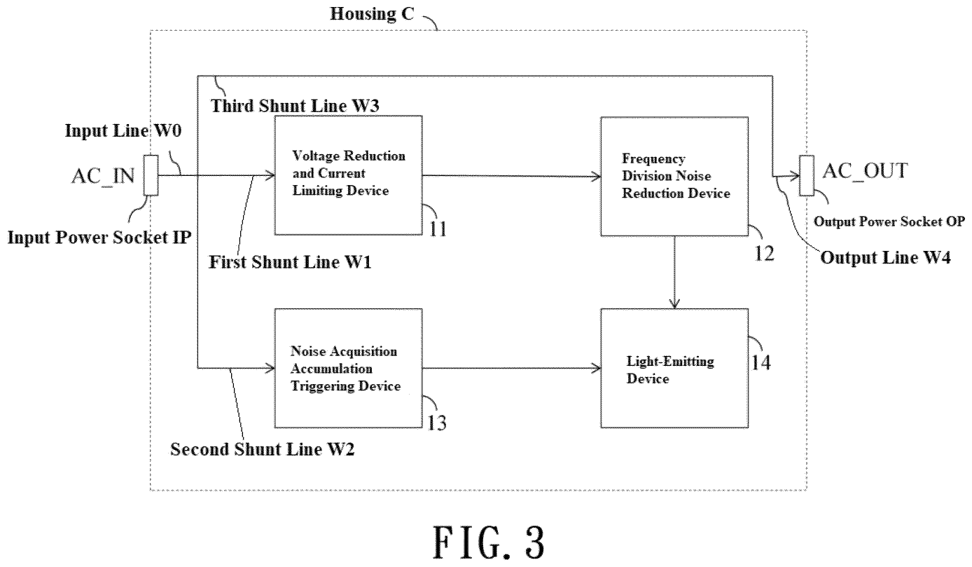

FIG. 3 is a block diagram of a power noise reduction adapter for enhancing food palatability of a food processing device according to the preferred embodiment of the present invention. The power noise reduction adapter 1 includes an input wire W0, a first shunt wire W1, a second shunt wire W2, a third shunt wire W3, a voltage reduction and current limiting device 11, a frequency division noise reduction device 12, a noise acquisition accumulation triggering device 13, and an output wire W4.

The input wire W0 is configured to receive an alternating current input power signal AC_IN. The input power signal AC_IN is an alternating current mains power signal. A frequency of the alternating current mains power signal AC_IN is 50 Hz or 60 Hz, and a voltage of the alternating current mains power signal AC_IN is any one of 100 volts, 110 volts, and 200 to 240 volts. However, the present invention is not limited thereto, and the voltage of the alternating current mains power signal AC_IN is ranged between 100 volts and 240 volts. For example, in Taiwan, the alternating current mains power signal AC_IN has a frequency of 60 Hz and a voltage of 110 volts.

The first shunt wire W1, the second shunt wire W2, and the third shunt wire W3 are electrically connected to the input wire W0. The input power signal AC_IN is shunted on the first shunt wire W1, the second shunt wire W2, and the third shunt wire W3 to generate a first shunt power signal, a second shunt power signal, and a third shunt power signal, respectively.

The voltage reduction and current limiting device 11 is electrically connected to the first shunt wire W1 and is configured to perform voltage reduction and current limiting on the first shunt power signal. The voltage reduction and current limiting device 11 includes a high-voltage capacitor and a current limiting device that are electrically connected to each other, so as to perform the voltage reduction and current limiting. The frequency division noise reduction device 12 is electrically connected to the voltage reduction and current limiting device 11 and is configured to perform at least one frequency division on the first shunt power signal after the voltage reduction and current limiting, and to output at least one frequency division signal. The frequency division noise reduction device 12 includes a plurality of frequency division units connected in series. The plurality of frequency division units are configured to perform one to multiple frequency divisions on the first shunt power signal, and to output a plurality of frequency division signals corresponding to the one to multiple frequency divisions. A division ratio of each of the plurality of frequency division units is an even number, such as 2. However, the present invention is not limited thereto, and the division ratio is also an odd number. In addition, an implementation manner of the frequency division noise reduction device 12 is not intended to limit the present utility model. The frequency division noise reduction device 12 may alternatively include a plurality of frequency division units connected in parallel.

The noise acquisition accumulation triggering device 13 is electrically connected to the second shunt wire W2 and is configured to acquire and accumulate a plurality of noise signals from the second shunt power signal, so as to generate a noise accumulation signal, and to output a trigger signal when the noise accumulation signal accumulates to a threshold value. In another embodiment, the noise acquisition accumulation triggering device 13 includes a pulse transformer and a control chip that are electrically connected to each other, so as to acquire and accumulate the plurality of noise signals. In another embodiment, the pulse transformer includes a high-voltage capacitor, such that the pulse transformer is a high-voltage capacitor pulse transformer. The pulse transformer is configured to acquire and accumulate the plurality of noise signals, and the control chip is configured to output the noise accumulation signal as the trigger signal when the noise accumulation signal accumulates to the threshold value. However, the present invention is not limited to the implementation manner of the noise acquisition accumulation triggering device. The output wire W4 is electrically connected to the third shunt wire W3 and is configured to use the third shunt power signal as the output power signal AC_OUT of the power noise reduction adapter 1.

The frequency division signal and the trigger signal are released to ground in a specific manner. Since the frequency division signal and the trigger signal are related to noise, after being released to ground, noise contained in the third shunt power signal obtained after shunting the input power signal AC_IN is equivalently reduced. Accordingly, the output power signal AC_OUT has reduced noise or is substantially free of noise. In this embodiment of the present invention, the power noise reduction adapter 1 further includes a light-emitting device 14. The light-emitting device 14 is electrically connected to the frequency division noise reduction device 12 and the noise acquisition accumulation triggering device 13. The light-emitting device 14 includes a plurality of light-emitting units and is configured to receive the trigger signal and the frequency division signal, wherein the plurality of light-emitting units emit light according to the trigger signal and the frequency division signal. Furthermore, in other embodiments, the light-emitting device 14 is replaced with, for example, a buzzer or other electroacoustic or photoelectric components. In brief, the light-emitting device 14 is used as a noise releasing device, and a purpose thereof is to release noise. Since the trigger signal and the frequency division signal are substantially composed of noise, the noise releasing device is mainly configured to receive and release the trigger signal and the frequency division signal.

When the power noise reduction adapter 1 is independently disposed outside the food processing device 2, the power noise reduction adapter 1 further includes a housing C. The input wire W0, the first shunt wire W1, the second shunt wire W2, the third shunt wire W3, the voltage reduction and current limiting device 11, the frequency division noise reduction device 12, the noise acquisition accumulation triggering device 13, and the light-emitting device 14 are disposed within the housing C. The housing C is provided with at least one opening, an input power socket IP, and an output power socket OP. The at least one opening is configured to expose a light-emitting portion of the light-emitting device 14. The input power socket IP and the output power socket OP are respectively configured to connect the input wire W0 and the output wire W4. In addition, the input power socket IP and the output power socket OP are respectively configured to connect an input power cable and an output power cable.

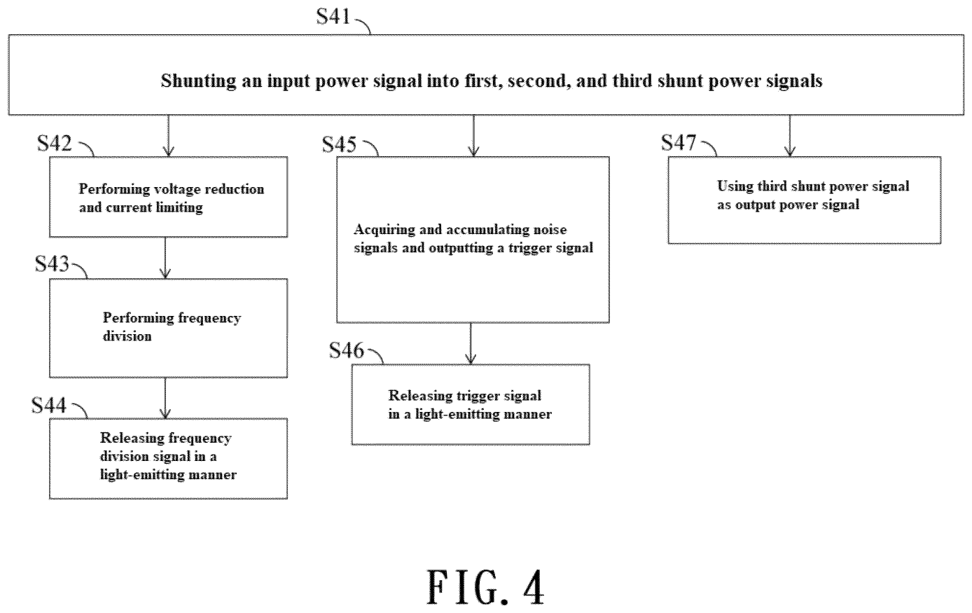

FIG. 4 is a flowchart of a power noise reduction method for enhancing food palatability of a food processing device according to the preferred embodiment of the present invention. The power noise reduction method for enhancing food palatability of a food processing device is performed by a power noise reduction adapter and includes the following steps. First, in step S41, an input power signal is shunted into a first shunt power signal, a second shunt power signal, and a third shunt power signal through a parallel connection. The first shunt power signal, the second shunt power signal, and the third shunt power signal are processed in parallel in “steps S42 to S44”, “steps S45 and S46”, and “step S47”, respectively.

In step S42, voltage reduction and current limiting are performed on the first shunt power signal. In step S43, at least one frequency division is performed on the first shunt power signal after the voltage reduction and current limiting, and at least one frequency division signal is output. In step S44, the at least one frequency division signal is presented in a light-emitting manner, so as to release the frequency division signal to ground. In step S45, a plurality of noise signals are acquired and accumulated from the second shunt power signal to generate a noise accumulation signal, and a trigger signal is output when the noise accumulation signal accumulates to a threshold value. In step S46, the trigger signal is presented in a light-emitting manner, so as to release the trigger signal to ground. In step S47, the third shunt power signal is used as an output power signal of the power noise reduction adapter.

Based on the above descriptions, the power noise reduction adapter and the electrical device serving as a food processing device provided by the present invention have at least the following features. (1) The input power signal is shunted into three shunt power signals. After two of the shunt power signals are subjected to specific processing, noise is released, such that noise contained in the other shunt power signal is correspondingly reduced. The other shunt power signal is then used as a purified output power signal for supplying power to an electrical device. (2) Since the electrical device uses the purified output power signal, performance and operational stability of the electrical device is improved. (3) When the electrical device is a food processing device, flavors of food produced by the food processing device are not adversely affected by noise of the power signal. Accordingly, for catering businesses, food having stable quality is provided to customers without a need to employ professional catering personnel.

When introducing elements of the present invention or the preferred embodiments thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the invention are achieved and other advantageous results attained.

As various changes could be made in the above constructions, products, and methods without departing from the scope of the invention, it is intended that all matter contained in the above description and shown in the accompanying drawings shall be interpreted as illustrative and not in a limiting sense.

What is claimed is:

1. A power noise reduction adapter, comprising:
an input wire (W0) configured to receive an alternating current input power signal (AC_IN);
a first shunt wire (W1), a second shunt wire (W2), and a third shunt wire (W3) electrically connected to the input wire (W0), wherein the input power signal (AC_IN) is shunted on the first shunt wire (W1), the second shunt wire (W2), and the third shunt wire (W3) to generate a first shunt power signal, a second shunt power signal, and a third shunt power signal;
a voltage reduction and current limiting device (11) electrically connected to the first shunt wire (W1) and configured to perform voltage reduction and current limiting on the first shunt power signal;
a frequency division noise reduction device (12) electrically connected to the voltage reduction and current limiting device (11) and configured to perform at least one frequency division on the first shunt power signal after the voltage reduction and current limiting, and to output at least one frequency division signal;
a noise acquisition accumulation triggering device (13) electrically connected to the second shunt wire (W2) and configured to acquire and accumulate a plurality of noise signals from the second shunt power signal to generate a noise accumulation signal, and to output a trigger signal when the noise accumulation signal accumulates to a threshold value;
an output wire (W4) electrically connected to the third shunt wire (W3) and configured to use the third shunt power signal as an output power signal (AC_OUT) of the power noise reduction adapter; and
a noise releasing device electrically connected to the frequency division noise reduction device (12) and the noise acquisition accumulation triggering device

(13) and configured to receive and release the frequency division signal and the trigger signal.

2. The power noise reduction adapter according to claim 1, wherein the noise releasing device is a light-emitting device (14) comprising a plurality of light-emitting units configured to receive the trigger signal and the frequency division signal, wherein the plurality of light-emitting units emit light according to the trigger signal and the frequency division signal.

3. The power noise reduction adapter according to claim 1, wherein the frequency division noise reduction device (12) comprises a plurality of frequency division units connected in series, the plurality of frequency division units being configured to perform one to multiple frequency divisions on the first shunt power signal, and to output a plurality of frequency division signals corresponding to the one to multiple frequency divisions.

4. The power noise reduction adapter according to claim 3, wherein a division ratio of each of the plurality of frequency division units is an even number.

5. The power noise reduction adapter according to claim 1, wherein the input power signal (AC_IN) is an alternating current mains power signal having a frequency of 50 Hz or 60 Hz and a voltage ranging from 100 volts to 240 volts.

6. The power noise reduction adapter according to claim 1, wherein the noise acquisition accumulation triggering device (13) comprises a high-voltage capacitor pulse transformer and a control chip electrically connected to each other to acquire and accumulate the plurality of noise signals, and the voltage reduction and current limiting device (11) comprises a high-voltage capacitor and a current limiting device electrically connected to each other to perform voltage reduction and current limiting.

7. The power noise reduction adapter according to claim 2, wherein the power noise reduction adapter (1) is independently disposed outside an electrical device and is electrically connected to a power module (21) of the electrical device, and the power module (21) receives the output power signal (AC_OUT) such that the electrical device uses the output power signal (AC_OUT).

8. The power noise reduction adapter according to claim 7, wherein the power noise reduction adapter (1) further comprises a housing (C), wherein the input wire (W0), the first shunt wire (W1), the second shunt wire (W2), the third shunt wire (W3), the voltage reduction and current limiting device (11), the frequency division noise reduction device (12), the noise acquisition accumulation triggering device (13), and the light-emitting device (14) are disposed within the housing (C), and the housing (C) is provided with at least one opening, an input power socket (IP), and an output power socket (OP), the at least one opening being configured to expose a light-emitting portion of the light-emitting device (14), the input power socket (IP) and the output power socket (OP) being respectively connected to the input wire (W0) and the output wire (W4), and the input power socket (IP) and the output power socket (OP) being respectively configured to connect an input power cable and an output power cable.

9. An electrical device, comprising:
a power module (21); and
the power noise reduction adapter (1) according to claim 1, electrically connected to the power module (21);
wherein the power module (21) receives the output power signal (AC_OUT) such that the electrical device uses the output power signal (AC_OUT).

10. The electrical device according to claim 9, wherein the electrical device is an espresso machine, a coffee grinder, a spice grinder, a bread maker, a brewing machine, a dairy fermentation machine, or a steam tea brewing machine.
